(19) United States
(12) Patent Application Publication
(10) Pub. No.: US 2012/0019116 A1
(43) Pub. Date: Jan. 26, 2012

(54) COMPUTER ENCLOSURE WITH DETACHABLE SIDE PANEL

(75) Inventor: CHEN-LU FAN, Tu-Cheng (TW)

(73) Assignee: HON HAI PRECISION INDUSTRY CO., LTD., Tu-Cheng (TW)

(21) Appl. No.: 13/070,900

(22) Filed: Mar. 24, 2011

(30) Foreign Application Priority Data
Jul. 26, 2010 (CN) 201010236807.7

(51) Int. Cl. H05K 5/02; A47B 81/00

(52) U.S. Cl. 312/312; 312/223.2

(57) ABSTRACT

A computer enclosure includes a frame and a side panel. An opening is defined at one side of the frame. The frame includes a retaining member. A securing slot is defined in the frame. The securing slot and the retaining member are located at opposite sides of the opening. The side panel covers the opening. The side panel includes a locking member and a retaining post. The retaining post extends into the securing slot. The locking member includes a block portion. The block portion is configured to elastically deform and ride over the retaining member to secure the side panel.

### BACKGROUND

1. Technical Field

The present disclosure relates to computer enclosures, especially to a computer enclosure with a side panel.

2. Description of Related Art

Generally, there are frequent occasions when a user must replace or repair hardware components disposed within a computer. To facilitate maintenance, a computer chassis may include a removable side panel. However, in such computers, the removable side panel is attached to the chassis by fasteners, and a tool is needed to remove or install the side panel. Therefore, an improved detachable side panel for allowing a user to easily replace and/or repair hardware components accommodated in a chassis is needed.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a computer enclosure.

FIG. 2 is similar to FIG. 1, but from another aspect.

FIG. 3 is an enlarged view of an encircled portion III of FIG. 2.

FIG. 4 is an enlarged view of an encircled portion IV of FIG. 1.

FIG. 5 is an enlarged view of an encircled portion V of FIG. 2.

FIG. 6 is an enlarged view of a locking member of FIG. 2, but from another aspect.

FIG. 7 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

An embodiment of a computer enclosure can be a server rack enclosure for receiving servers or an enclosure for receiving computer hardware directly.

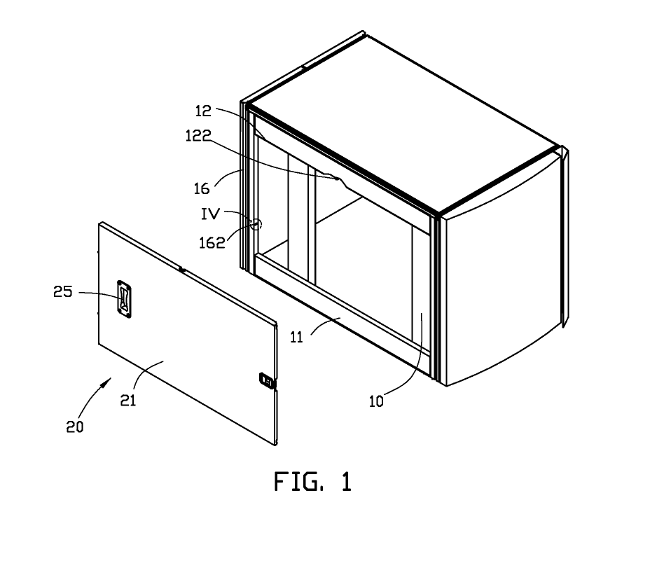

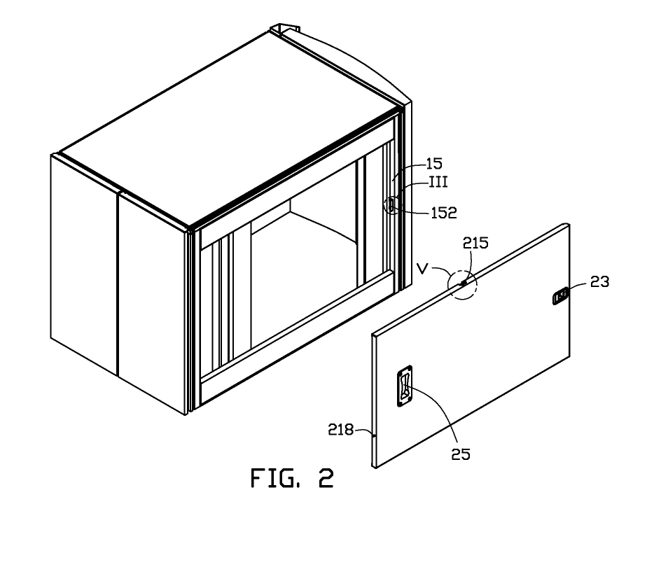

Referring to FIG. 1 and FIG. 2, the computer enclosure includes a frame 10 and a side panel 20 mounted to the frame 10. The frame 10 defines an opening for receiving servers or computer hardware. The frame 10 includes a bottom plate 11, a top plate 12, a front column 15, and a back column 16. The bottom plate 11 and the top plate 12 are parallel to each other. The front column 15 and the back column 16 are parallel to each other. A securing post 122 protrudes from the top plate 12.

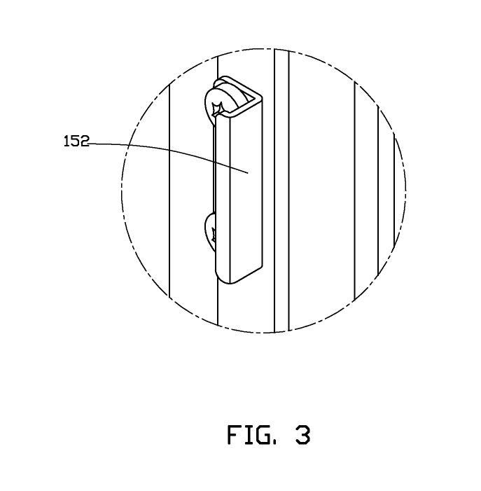

Referring to FIG. 3, a retaining member 152 is located at the front column 15. The retaining member 152 has an L-shaped cross section and extends to the back column 16.

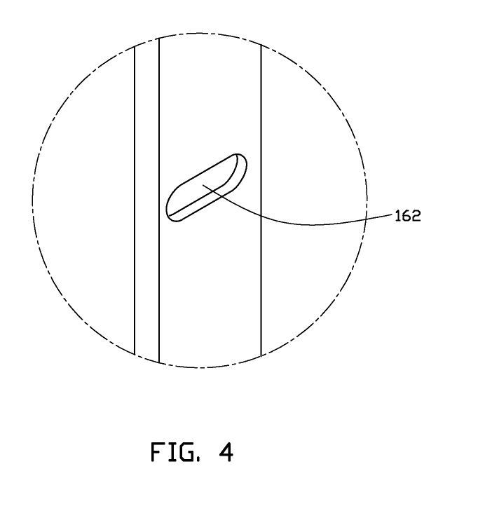

Referring to FIG. 4, a securing slot 162 is defined in the back column 16. An extending direction of the securing slot 162 is perpendicular to a plane defined by the front column 15 and the back column 16.

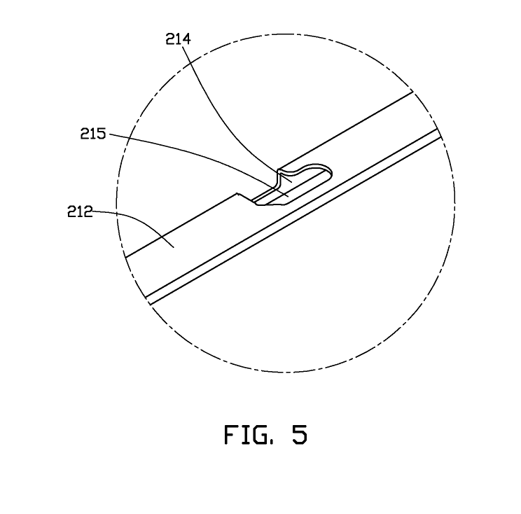

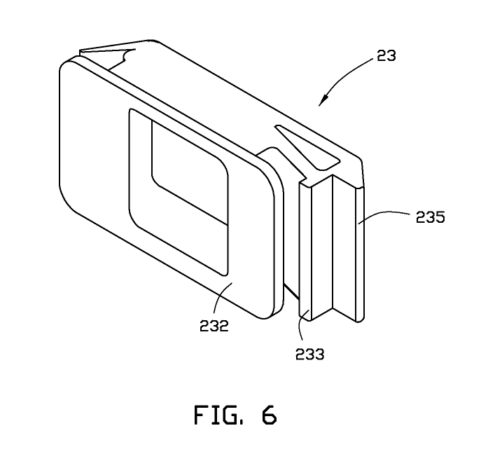

Referring to FIG. 5 and FIG. 6, the side panel 20 includes a base board 21, a locking member 23, and a handle 25. The base board 21 includes a top flange 212 and a side flange 214 that is perpendicular to the top flange 212. A guiding slot 215 is defined in the top flange 212 and extends into the side flange 214. The guiding slot 215 in the top flange 212 extends along a direction parallel to the base board 21. A retaining post 218 protrudes from a back side of the base board 21 corresponding to the securing slot 162. The handle 25 is located on the base board 21. A recess is defined in the handle 25 for receiving a user's finger.

The locking member 23 includes a base 232, a ridge 233 and an elastic block portion 235 is located on the base 232. The block portion 235 includes a wedge surface. A recess is defined in the base 232 for receiving a user's finger.

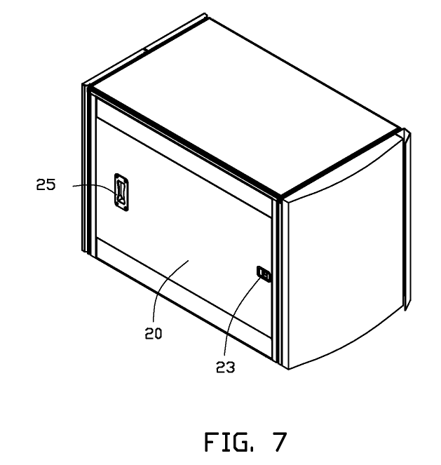

Referring to FIG. 7, in assembly, the side panel 20 is located on the opening of the frame 10 with the retaining post 218 aligned with the securing slot 162. The securing post 122 extends into the guiding slot 215 from the side flange 214 of the base board 21. The side panel 20 is moved towards the back column 16 of the frame 10. The retaining post 218 moves into the securing slot 162 and the securing post 122 goes into the guiding slot 215. The block portion 235 of the locking member 23 abuts on the retaining member 152 on an outer side of the retaining member 152. In this state, the side panel 20 is oblique to the plane defined by the front column 15 and back column 16. The side panel 20 is pushed into the frame 10 on the locking member 23. The block portion 235 is elastically deformed and rides over the retaining member 152 and engages with the retaining member 152. The side panel 20 is mounted on the frame 10 and covers the opening of the frame 10.

In disassembly, the side panel 20 is moved towards the front column 15. The block portion 235 is configured to elastically deform under pressure from the front column 15, so that the retaining post 218 is removed from the securing slot 162. The securing post 122 goes out of the guiding slot 215. The side panel 20 can then be removed from the frame 10 by operating the handle 25.

It is also to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A computer enclosure comprising:
a frame, an opening defined at one side of the frame, the frame comprising a retaining member, a securing slot defined in the frame, and the securing slot and the retaining member being located at opposite sides of the opening; and
a side panel covering the opening, the side panel comprising a locking member and a retaining post, wherein the retaining post extends into the securing slot;
wherein the locking member comprises a block portion, and the block portion is configured to elastically deform and ride over the retaining member to secure the side panel.

2. The computer enclosure of claim 1, wherein the frame comprises a top plate and a bottom plate, and the side panel is located between the top plate and the bottom plate.

3. The computer enclosure of claim 1, wherein the side panel further comprises a base board, the locking member is located on the base board, and the locking member defines a recess for receiving a user's finger.

4. The computer enclosure of claim 3, wherein the securing slot is perpendicular to the base board.

5. The computer enclosure of claim 4, wherein the base board comprises a top flange and a side flange perpendicular to the top flange, and a guiding slot is defined in the top flange and extends to the side flange; a securing post is located on the frame corresponding to the guiding slot.

6. The computer enclosure of claim 5, wherein the guiding slot in the top flange extends along a direction parallel to the base board.

7. The computer enclosure of claim 3, wherein the locking member comprises a ridge, and the ridge abuts on the base board.

8. The computer enclosure of claim 1, wherein the retaining member is L-shaped.

9. The computer enclosure of claim 1, wherein the block portion has a wedge surface.

10. A computer enclosure comprising:
a frame, an opening defined at one side of the frame, the frame comprising a retaining member, a securing slot defined in the frame, and the securing slot and the retaining member being located at opposite sides of the opening; and
a side panel covering the opening, the side panel comprising a locking member and a retaining post, the retaining post extending into the securing slot, and the locking member engaged with the retaining member;
wherein the locking member comprises a block portion, and the block portion is configured to elastically deform with a movement of side panel to remove the retaining post from the securing slot.

11. The computer enclosure of claim 10, wherein the frame comprises a top plate and a bottom plate, and the side panel is located between the top plate and the bottom plate.

12. The computer enclosure of claim 10, wherein the side panel further comprises a base board, the locking member is located on the base board, and the locking member defines a recess for receiving a user's finger.

13. The computer enclosure of claim 12, wherein the securing slot is perpendicular to the base board.

14. The computer enclosure of claim 13, wherein the base board comprises a top flange and a side flange that is perpendicular to the top flange, and a guiding slot is defined in the top flange and extends to the side flange; a securing post is located on the frame corresponding to the guiding slot.

15. The computer enclosure of claim 14, wherein the guiding slot in the top flange extends along a direction parallel to the base board.

16. The computer enclosure of claim 12, wherein the locking member comprises a ridge, and the ridge abuts on the base board.

17. The computer enclosure of claim 10, wherein the retaining member is L-shaped.

18. The computer enclosure of claim 10, wherein the block portion has a wedge surface.
